(19) United States
(12) Patent Application Publication
(10) Pub. No.: US 2008/0290530 A1
(43) Pub. Date: Nov. 27, 2008

(54) SEMICONDUCTOR DEVICE HAVING PHOTO ALIGNING KEY AND METHOD FOR MANUFACTURING THE SAME

(76) Inventor: Young Je YUN, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/126,187

(22) Filed: May 23, 2008

(30) Foreign Application Priority Data
May 25, 2007 (KR) 10-2007-0050897

(51) Int. Cl. H01L 23/544; H01L 21/00

(52) U.S. Cl. 257/797; 438/800; 257/E23.179; 257/E21.002

(57) ABSTRACT

Embodiments consistent with the present invention provide a semiconductor device having a photo aligning key and a method for manufacturing the same. The semiconductor device includes a pattern photo aligning key formed on a scribe line of a semiconductor substrate, and a plurality of dummy pattern keys formed around the pattern photo aligning key, the dummy pattern keys having a width smaller than that of the pattern photo aligning key.

### RELATED APPLICATION

This application claims the benefit of priority to Korean patent application no. 10-2007-0050897, filed on May 25, 2007, the entire contents of which are incorporated herein by reference.

1. Technical Field

Embodiments consistent with the present invention relate to a semiconductor device and a method for manufacturing the semiconductor device, and more particularly, to a semiconductor device having a photo aligning key and a method for manufacturing the semiconductor device.

2. Background

In general, a contact-to-silicon (CS) layer of a semiconductor device is formed by filling a contact metal, such as tungsten (W), in a contact hole and polishing the contact metal using a chemical mechanical polishing (CMP) process. Normally, device elements having a greater area, or wide patterns, have a polishing rate greater than those having a smaller area. For example, a photo aligning key positioned in a scribe lane can be considered as a wide pattern with respect to the contact hole. Specifically, the photo aligning key usually has a width of about 1 μm to about 6 μm, and the contact hole usually has a diameter of about 1 nm to about 150 nm. Accordingly, the polishing rate of the photo aligning key is much greater than that of the contact hole. Therefore, after polishing the contact hole, the photo aligning key is eroded, which causes a problem in reading the photo aligning key in a photo process of a metal layer process.

Therefore, when a copper (Cu) damascene process is used for the upper part of the contact hole, a dielectric layer is deposited after performing the CMP process on W. If the dielectric layer is transparent to a light ray and the light ray reflected from the photo aligning key can be used to distinguish the photo aligning key, then there is no problem reading the photo aligning key.

However, when aluminum (Al) is formed after performing the CMP on W, as shown in FIG. 1, the photo aligning key can be read only if a step difference is formed in the key pattern.

Specifically, referring to FIG. 2A, in the case of a Cu based metal layer, since a metal photo process is performed after forming a dielectric layer 200, it is possible to read the photo aligning key by using a visible light ray transparent to dielectric layer 200, because the reflectance of tungsten 202 is different from that of a pre-metal dielectric (PMD) layer 204. However, as illustrated in FIG. 2B, in the case of an Al based metal layer 210, since a visible light ray is totally reflected by metal layer 210, it is not possible to read the photo aligning key without the step difference.

In order to solve this problem, the thickness of PMD layer 204 is optimized so as to enlarge a polishing margin. However, since one must change the vertical topology of the semiconductor device if the thickness of PMD layer 204 is to be optimized, the operation characteristic of the semiconductor device may be deteriorated. Accordingly, it is not possible to secure the reliability of the semiconductor device.

### SUMMARY

Embodiments consistent with the present invention provide a semiconductor device having a photo aligning key and a method for manufacturing the same.

In one embodiment consistent with the present invention, the semiconductor device includes a wide pattern photo aligning key formed on a scribe line of a semiconductor substrate, and a plurality of dummy pattern keys formed around the wide pattern photo aligning key, the dummy pattern keys having a width smaller than that of the wide pattern photo aligning key.

In another embodiment consistent with the present invention, the method includes forming a wide pattern photo aligning key on a scribe line of a semiconductor substrate, forming a plurality of holes in an insulating layer formed on the semiconductor substrate and around the photo aligning key, the holes having a width smaller than that of the wide pattern photo aligning key, and forming a plurality of dummy pattern keys by filling a metal material in the holes formed in the insulating layer.

### BRIEF DESCRIPTION OF THE DRAWINGS

FIG. 1 illustrates a scanning electron microscope (SEM) photograph of a conventional photo aligning key.

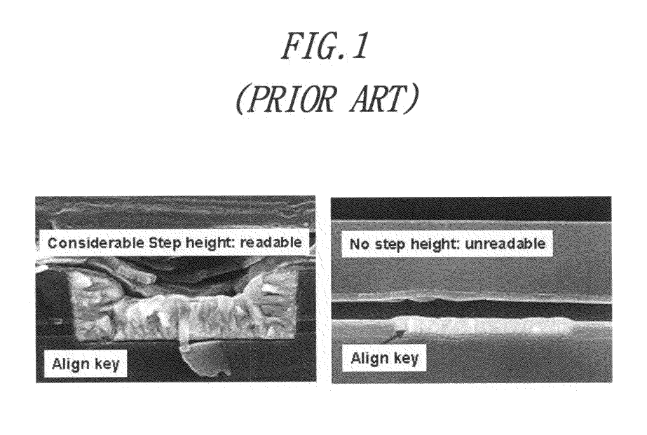

FIG. 2 is a sectional view illustrating a conventional dense photo key formed in a damascene process.

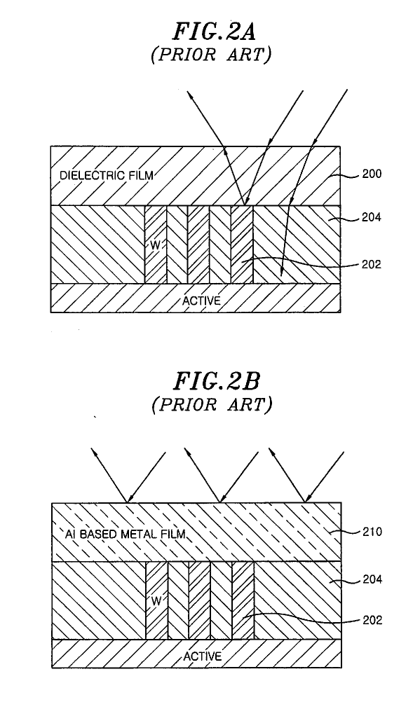

FIGS. 3A to 3C are sectional views illustrating a wide pattern photo aligning key of a semiconductor device according to an embodiment consistent with the present invention.

FIGS. 4A to 4C are sectional views illustrating an eroded wide pattern photo aligning key of a semiconductor device.

FIGS. 5A to 5C are plane views illustrating a wide pattern photo aligning key of a semiconductor device according to embodiments consistent with the present invention.

### DETAILED DESCRIPTION

Hereinafter, embodiments consistent with the present invention will be described in detail with reference to the accompanying drawings so that they can be readily implemented by those skilled in the art.

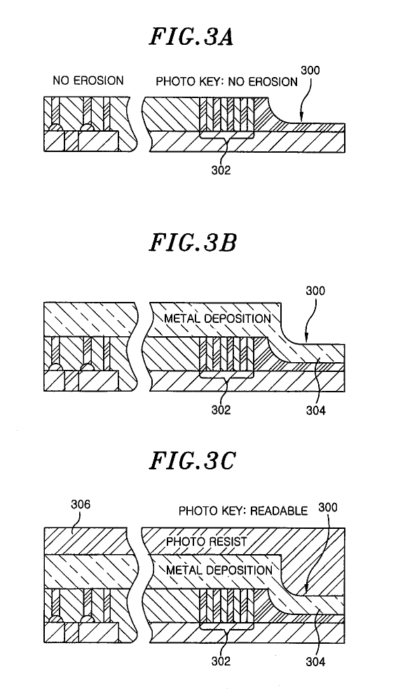

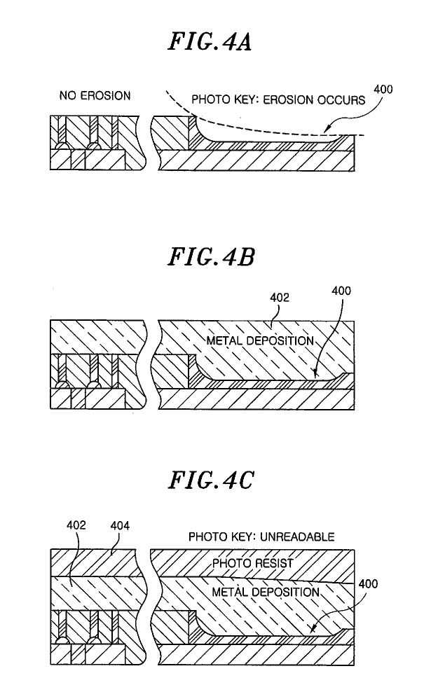

FIGS. 3A to 3C are sectional views illustrating a photo aligning key and a photo process capable of producing a readable photo aligning key, according to an embodiment consistent with the present invention. Hereinafter, the readable photo aligning key will be described in comparison with an unreadable photo aligning key illustrated in FIGS. 4A to 4C.

Referring to FIG. 4A, a photo aligning key 400, which may be a wide pattern, is eroded by a chemical mechanical polishing (CMP) process performed on a contact metal 401, such as W, so that a step difference is removed. Referring to FIG. 4B, when a metal layer 402 is deposited on photo aligning key 400, a step difference is not formed in metal layer 402. Therefore, referring to FIG. 4C, after depositing a photoresist layer 404 on metal layer 402 in a metal photo process for etching metal layer 402, it may be impossible to read photo aligning key 400.

Therefore, in order to prevent photo aligning key 400 from being eroded in the CMP process for contact metal 401, one or more dummy pattern keys may be formed in a dense hole or a dense space around photo aligning key 400 to protect photo aligning key 400.

Referring to FIG. 3A, dense holes or dense spaces, in which a dummy pattern key 302 is to be formed, are formed in an insulating layer 305 and around a wide pattern photo aligning key 300. Dummy pattern key 302 formed in the dense holes or the dense spaces may prevent photo aligning key 300 from being eroded in the CMP process for a contact metal 301.

In one embodiment, dummy pattern keys 302 may be formed after forming wide pattern photo aligning key 300 for interlayer alignment of a semiconductor device. To form dummy pattern key 302, a photoresist mask (not shown) may be formed on insulating layer 305, and insulating layer 305 may be patterned using the photoresist mask as an etching mask. As a result, a plurality of dummy patterns is formed in insulating layer 305 and around photo aligning key 300. In one embodiment, the dummy patterns may include holes having a width of about 100 nm to about 200 nm, which is smaller than the width (for example, 1 μm) of photo aligning key 300. Then, after the dummy patterns around photo aligning key 300 are formed, a metal material may be gap filled in the dummy patterns to form dummy pattern key 302. In one embodiment, a ratio of the width of photo aligning key 300 to that of dummy pattern key 302 may be from about 10:1 to about 20:1. As discussed above, dummy pattern key 302 may prevent photo aligning key 300 from being eroded.

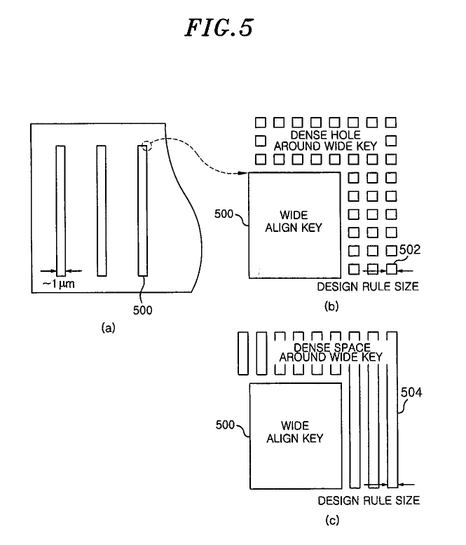

FIG. 5A is a plane view illustrating photo aligning key 500 formed on a semiconductor substrate consistent with the present invention. In one embodiment, photo aligning key 500 may have a width of about 1 μm.

As illustrated in FIG. 5B, dense holes 502 are formed around photo aligning key 500. In one embodiment, dense holes 502 may have a square shape with a width of about 100 nm to about 200 nm. In one embodiment, dense holes 502 may be filled with a metal material so as to form a dummy pattern key, which may prevent pattern photo aligning key 500 from being eroded.

As illustrated in FIG. 5C, dense spaces 504 are formed around photo aligning key 500. In one embodiment, dense spaces 504 may have a rectangular shape and may be filled with a metal material so as to form a dummy pattern key, which may have a width of about 100 nm to about 200 nm. The dummy pattern key formed in dense spaces 504 may prevent photo aligning key 500 from being eroded.

Referring back to FIG. 3B, a metal layer 304 is deposited on wide pattern photo aligning key 300, which is not eroded when the CMP process is performed on contact metal 301 due to the presence of dummy pattern key 302 formed of the above-described dense holes or dense spaces. As a result, metal layer 304 forms a step difference on photo aligning key 300, because photo aligning key 300 is not eroded.

Therefore, as illustrated in FIG. 3C, after depositing a photoresist layer 306 on metal layer 304 in a metal photo process for etching metal layer 304, it is possible to read photo aligning key 300 due to the step difference formed in metal layer 304.

While embodiments consistent with the present invention have been shown and described, it will be understood by those skilled in the art that various changes and modifications may be made without departing from the spirit and scope of the appended claims.

What is claimed is:

1. A semiconductor device, comprising:
a pattern photo aligning key formed on a scribe line of a semiconductor substrate; and
a plurality of dummy pattern keys formed around the pattern photo aligning key, the dummy pattern keys having a width smaller than that of the pattern photo aligning key.

2. The device of claim 1, wherein a ratio of the width of the photo aligning key to the width of the dummy pattern keys is set from about 10:1 to about 20:1.

3. The device of claim 2, wherein the dummy pattern keys are formed in a dense hole having a width of about 100 nm to about 200 nm.

4. The device of claim 2, wherein the dummy pattern key is formed in a dense space having a width of about 100 nm to about 200 nm.

5. A method for fabricating a semiconductor device, comprising:
forming a pattern photo aligning key on a scribe line of a semiconductor substrate;
forming a plurality of holes in an insulating layer formed on the semiconductor substrate and around the photo aligning key, the holes having a width smaller than that of the wide pattern photo aligning key; and
forming a plurality of dummy pattern keys by filling a metal material in the holes.

6. The method of claim 5, wherein a ratio of the width of the photo aligning key to that of the dummy pattern keys is set to be from about 10:1 to about 20:1.

7. The method of claim 5, wherein forming the dummy pattern keys comprises filling tungsten in the holes.

8. The method of claim 6, wherein forming the holes comprises forming a dense hole having a width of about 100 nm to about 200 nm.

9. The method of claim 6, wherein forming the holes comprises forming a dense space having a width of about 100 nm to about 200 nm.

10. The method of claim 6, wherein forming the pattern photo aligning key comprises forming the pattern photo aligning key having a width of about 1 μm to 10 μm on the scribe line of the semiconductor substrate.
